(19) United States
(12) Patent Application Publication
(10) Pub. No.: US 2014/0159084 A1
(43) Pub. Date: Jun. 12, 2014

(54) LED DOME WITH IMPROVED COLOR SPATIAL UNIFORMITY

(71) Applicant: CREE, INC., Durham, NC (US)

(72) Inventors: Mario Castillo, Racine, WI (US); Kurt Wilcox, Libertyville, IL (US)

(73) Assignee: CREE, INC., Durham, NC (US)

(21) Appl. No.: 13/804,309

(22) Filed: Mar. 14, 2013

Related U.S. Application Data
(60) Provisional application No. 61/736,461, filed on Dec. 12, 2012.

(51) Int. Cl. H01L 33/58; H01L 33/54

(52) U.S. Cl. CPC H01L 33/58; H01L 33/54
USPC 257/98; 438/27

(57) ABSTRACT

A light emitting diode (LED) package comprising an encapsulant designed to improve color spatial uniformity in comparison to hemispherical encapsulants is described. In some embodiments, the encapsulant comprises a segment of a hemisphere as a lower portion and an upper portion of a second shape. In some embodiments this second shape is defined by a spline curve. The encapsulant improves color uniformity over a wide range of angles while only minimally affecting other attributes such as photometric polar distribution, extraction efficiency, and luminous intensity. Embodiments of the present invention can also utilize light emitting systems comprising such LED packages.

### RELATED APPLICATION

This application claims the benefit of U.S. Provisional Application No. 61/736,461, filed on 12 Dec. 2012, which is incorporated by reference herein in its entirety.

### BACKGROUND OF THE INVENTION

1. Field of the Invention

The invention relates generally to LED packages and, more particularly, to encapsulants within LED device packages.

2. Description of the Related Art

Light emitting diodes (LED or LEDs) are solid state devices that convert electric energy to light, and generally comprise one or more active layers of semiconductor material sandwiched between oppositely doped layers. Typically, wire bonds are used to apply a bias across the doped layers, injecting holes and electrons into the active layer where they recombine to generate light. Light is emitted from the active layer and from all surfaces of the LED. A typical high efficiency LED comprises an LED chip mounted to an LED package and encapsulated by a transparent medium. The efficient extraction of light from LEDs and the quality of that light are major concerns in LED package fabrication.

LEDs can be fabricated to emit light in various colors. However, conventional LEDs cannot generate white light from their active layers. Light from a blue emitting LED has been converted to white light by surrounding the LED with a yellow phosphor, polymer or die, with a typical phosphor being cerium-doped yttrium aluminum garnet (Ce:YAG). [See Nichia Corp. white LED, Part No. NSPW300BS, NSPW312BS, etc.; See also U.S. Pat. No. 5,959,316 to Lowrey, “Multiple Encapsulation of Phosphor-LED Packages”]. The surrounding phosphor material “downconverts” the energy of some of the LED's blue light which increases the wavelength of the light, changing its color to yellow. Some of the blue light passes through the phosphor without being changed while a different portion of the light is downconverted to yellow. The LED package or device (used herein interchangeably) emits both blue and yellow light, which combine to provide a white light. In another approach light from a violet or ultraviolet emitting LED has been converted to white light by surrounding the LED with multicolor phosphors or die. Many different types of LED die can be used individually or in combination in an LED package based on the package application. Possible die include DA, EZ, GaN, MB, RT, TR, UT, and XT LED die, commercially available from Cree, Inc.

LED packages typically have some type of encapsulant surrounding the LED chip. The encapsulant can serve multiple purposes, including but not limited to suspending phosphor particles in place above the emitting LED chip, enhancing light extraction from the package, and/or protecting the chip and related contacts structure (e.g., wire bonds) from exposure to physical damage or environmental conditions which could lead to corrosion or degradation. Along with this encapsulant, a primary optical element such as a lens may also be used. Primary lenses can completely surround an LED chip and the encapsulant. In other cases, the encapsulant itself can serve as the primary lens. The encapsulant and/or the lens can adhere directly to an LED chip and/or mount surface, or can be attached to the LED chip and/or mount surface using another material such as an adhesive epoxy. The encapsulant, the lens, or the combination of the two can enhance light extraction from the package and provide some form of output light beam shaping (control over the angle-dependent properties of the package).

In addition to an encapsulant, an LED package may comprise one or more secondary optics for various purposes, including but not limited to beam shaping. Different secondary optics can have different beam shaping effects; for instance, a secondary optic with Illuminating Engineering Society North American T5 specifications causes peak emission at a relatively wide angle.

In a typical LED apparatus the encapsulant has a central axis generally perpendicular to the LED base or substrate. The light passing through such an encapsulant and/or lens produces an illumination pattern which is substantially rotationally symmetric around this central axis. Once emitted from the LED chip, a ray of light will encounter the boundary at the edge of the encapsulant (often an encapsulant/air boundary). When a ray of light strikes a medium boundary at an angle perpendicular to that boundary, the light continues straight on its path. However, when a ray of light strikes a medium boundary (where the first material has a different index of refraction than the second material) at an angle of incidence greater than the critical angle as defined by Snell's law, the ray of light experiences total internal reflection (TIR) such that no light is emitted through the boundary. When a ray of light strikes a medium boundary at any angle between perpendicular and the critical angle, a portion of the light is reflected internally and a portion is refracted. Encapsulants can therefore be formed into many shapes to shape a beam of light based on this optical phenomenon. LED packages that minimize TIR have high extraction efficiencies, and because even at high angles little if any light is internally reflected, have a wide photometric distribution.

FIGS. 1A and 1B show a perspective view and a cross-sectional illustration of a known LED package 100, respectively. The package comprises an encapsulant 102 that is disposed above one or more light sources 106 such that substantially all of the light emitted from the source 106 has to pass through the encapsulant 102. The encapsulant 102 comprises a primary emission surface 104 that is dome-shaped. The primary emission surface 104 is shaped this way in order to maximize the percentage of light from the source 106 that encounters the surface 104 at a right angle. Such light will pass through the primary emission surface 104 without substantial internal reflection, and therefore the LED package 100 will experience minimal TIR.

The relative color appearance of a light source can be measured by its correlated color temperature (CCT) measured in Kelvin (K). As the CCT of white light becomes high (e.g., 6500K, or the CCT of an electronic camera flash), the light appears to have a bluer tint and is considered cool. As the CCT of white light becomes lower (e.g., 1700K, or the OCT of a match flame), the light appears to have more of a yellow tint and is considered warm. A white light LED package with perfect CSU will emit light of the same CCT at all angles, whereas a white light LED package with poor CSU may emit light with a COT that is highly variable based on viewing angle from the optical axis.

Any number of design features, including encapsulant shape and composition, can have an effect on an LED package's CSU. A package with improved CSU will be capable of use in strongly angle-dependent applications. One goal of modern LED package design is to improve emission characteristics such as CSU while maintaining other emission characteristics, such as extraction efficiency and near and far field photometric distribution, at acceptable levels.

It is not always desirable to use a dome-shaped encapsulant. Other factors, such as the output CSU of the package, must be taken into account. While dome-shaped encapsulants are shaped to minimize TIR, they are not designed to optimize CSU for multiple reasons. One such reason is that phosphor distribution within the encapsulant may be uneven. Another reason is that a phosphor coating deposited on the LED chip may be uneven. Yet another reason is that in certain embodiments, light emitted at different angles from the LED chip may take paths of different length to the emission surface of the encapsulant, and thus have more or less light converted by phosphors within the encapsulant. It should be noted that while these are exemplary factors affecting CSU, many other factors exist. As such, light at certain angles of emission could have a blue or yellow tint.

As LED technology has become more advanced (e.g., blue-emitting LED chips used with yellow phosphors to produce white light), the optics used in LED packages have not necessarily advanced at the same pace. Many packages utilizing these advanced LED technologies also utilize older optic technologies, such as encapsulants and lenses defined by a single hemispherical curve. When combined with newer LED technologies, such as the die used in the XLamp XT-E White LED package available from Cree, Inc., these older optical packages may emit light with certain qualities that can be situationally undesirable. Such characteristics can include, but are not limited to, near and far field CSU and near field photometric distribution.

### SUMMARY OF THE INVENTION

Briefly, and in general terms, the invention is directed to a light emitting diode (LED) package having improved color spatial uniformity (CSU). In some embodiments, the LED package can comprise an encapsulant that is shaped to emit light with improved CSU.

One embodiment of an LED package according to the present invention comprises an LED chip and a shaped encapsulant over the LED chip. The encapsulant has an upper portion and a lower portion. The upper portion is one shape, whereas the lower portion is a second shape. The upper portion and lower portion combine to improve the CSU of the package.

One embodiment of an encapsulant according to the present invention comprises an upper portion and a lower portion. The upper portion has a first shape with a spline curve cross-section, while the lower portion has a second shape.

One embodiment of a light emitting system according to the present invention comprises an LED chip and a shaped encapsulant comprising an upper portion of a first shape and a lower portion of a second shape over the LED chip. The system further comprises a secondary optic. The upper portion and lower portion of the encapsulant combine to improve the CSU of the package.

Another embodiment of an LED package according to the present invention comprises an LED chip and a shaped encapsulant over the LED chip. The encapsulant refracts at least some of a first portion of light emitted from the LED chip away from the optical axis, and refracts at least some of a second portion of light toward the optical axis.

Another embodiment of an LED package according to the present invention comprises an LED chip and a shaped encapsulant over the LED chip. The source optical axis and the package optical axis are not coincident.

One embodiment of a method for fabricating an LED package comprises providing a mount surface and disposing an LED chip on the mount surface. The embodiment further comprises depositing a first encapsulant section onto the LED chip, depositing a second encapsulant section onto the LED chip, curing the first encapsulant section, and curing the second encapsulant section.

One embodiment of a method for fabricating a plurality of LED packages comprises providing a wafer, disposing a plurality of LED chips on the wafer, depositing a plurality of first encapsulant sections of a first shape and a plurality of second encapsulant sections of a shape on the LEDs, and shaping the encapsulant sections by a mold while they are cured.

Another embodiment of an LED package according to the present invention comprises an LED chip and a shaped encapsulant over the LED chip. The encapsulant has a convex upper portion and a convex lower portion. The upper portion is one shape, whereas the lower portion is a second shape.

These and other embodiments and advantages of the invention will become apparent from the following detailed description and the accompanying drawings which illustrate by way of example the features of the invention.

### BRIEF DESCRIPTION OF THE DRAWINGS

FIG. 1A and FIG. 1B are a perspective view and a cross-sectional view of a prior art LED package comprising a dome-shaped encapsulant.

FIG. 2 is a cross-sectional view of an LED package comprising an encapsulant according to an embodiment of the present invention.

FIG. 3A is a magnified cross-sectional view of an encapsulant according to an embodiment of the present invention.

FIG. 3B is a cross-sectional diagram of an encapsulant comprising a lower portion and possible upper portion designs.

FIG. 4A and FIG. 4B are ray trace diagrams of a prior art LED package and an LED package according to an embodiment of the present invention, respectively.

FIG. 5A and FIG. 5B are ray trace diagrams of a prior art LED package and an LED package according to an embodiment of the present invention, respectively. Both packages comprise a secondary optic.

FIGS. 6A and 6B are ray trace diagrams of high intensity blue light leakage from a prior art LED package and an LED package according to an embodiment of the present invention, respectively.

FIGS. 7A and 7B are ray trace diagrams of high intensity blue light leakage from a prior art LED package and a package according to an embodiment of the present invention, respectively. Both packages comprise a secondary optic.

FIG. 8A is a CCT vs. emission angle graph of a prior art LED package and an LED package according to an embodiment of the present invention, respectively.

FIG. 8B is a COT vs. emission angle graph of the devices, further comprising a secondary optic.

FIG. 8C is similar to FIG. 8B, wherein the devices comprise a secondary optic different than that of FIG. 8B.

FIGS. 9A and 9B are photometric distribution diagrams of a prior art LED package and an LED package according to an embodiment of the present invention, respectively.

FIGS. 10A and 10B are photometric distribution diagrams of a prior art LED package comprising a secondary optic and an LED package comprising the secondary optic according to an embodiment of the present invention, respectively.

FIGS. 11A and 11B are photometric distribution diagrams of a prior art LED package comprising a different secondary optic and an LED package comprising the different secondary optic according to an embodiment of the present invention, respectively.

FIGS. 12A and 12B show a perspective and a front view of a light emitting system comprising an LED package according to the present invention.

FIGS. 13A and 13B show a perspective and a front view of another embodiment of a light emitting system comprising an LED package according to the present invention.

FIGS. 14A, 14B, and 14C show a perspective view, front view, and side view of an LED device comprising an asymmetric encapsulant according to the present invention.

FIG. 15 is a perspective view of a lighting unit comprising multiple LED packages according to the present invention.

FIG. 16 is a perspective view of a downlight fixture comprising multiple LED packages according to the present invention.

### DETAILED DESCRIPTION OF THE INVENTION

The present invention provides embodiments of an LED package comprising an encapsulant that helps to improve color spatial uniformity (CSU) while maintaining acceptable photometric distribution and extraction efficiency. For white light LED packages, the color of emitted light can be measured by its correlated color temperature (CCT), which may vary based on viewing angle due to a number of factors. An LED package with good CSU will emit light of relatively constant CCT across most viewing angles.

Encapsulants can be formed into many shapes to achieve various design goals. Some LED packages include a dome-shaped or hemispheric encapsulant disposed over the LED chip in order to reduce the total internal reflection (TIR) of the emitted light, as previously discussed. The present invention, on the other hand, utilizes a non-hemispheric encapsulant to improve CSU while minimizing any effect on extraction efficiency and photometric distribution. One embodiment of the present invention comprises an encapsulant symmetric about the source optical axis with a lower hemispheric portion and an upper portion with a cross-section defined by a spline curve. Other embodiments can comprise encapsulants with one or more asymmetric portions, symmetric encapsulants that are displaced from the source optical axis, encapsulant portions with different indexes of refraction, and/or encapsulants comprising more than two portions.

It is understood that when an element is referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one element to another. Terms such as “higher”, “lower”, “wider”, “narrower”, and similar terms, may be used herein to describe angular relationships. It is understood that these terms are intended to encompass different orientations of the package in addition to the orientation depicted in the figures.

Although the terms first, second, etc., may be used herein to describe various elements, components, regions and/or sections, these elements, components, regions, and/or sections should not be limited by these terms. These terms are only used to distinguish one element, component, region, or section from another. Thus, unless expressly stated otherwise, a first element, component, region, or section discussed below could be termed a second element, component, region, or section without departing from the teachings of the present invention.

As used herein, the term “source” can be used to indicate a single light emitter or more than one light emitter functioning as a single source. Thus, the term “source” should not be construed as a limitation indicating either a single-element or a multi-element configuration unless clearly stated otherwise.

Embodiments of the invention are described herein with reference to cross-sectional view illustrations that are schematic illustrations. As such, the actual thickness of elements can be different, and variations from the shapes of the illustrations as a result, for example, of manufacturing techniques and/or tolerances are expected. Thus, the elements illustrated in the figures are schematic in nature and their shapes are not intended to illustrate the precise shape of a region of a package and are not intended to limit the scope of the invention.

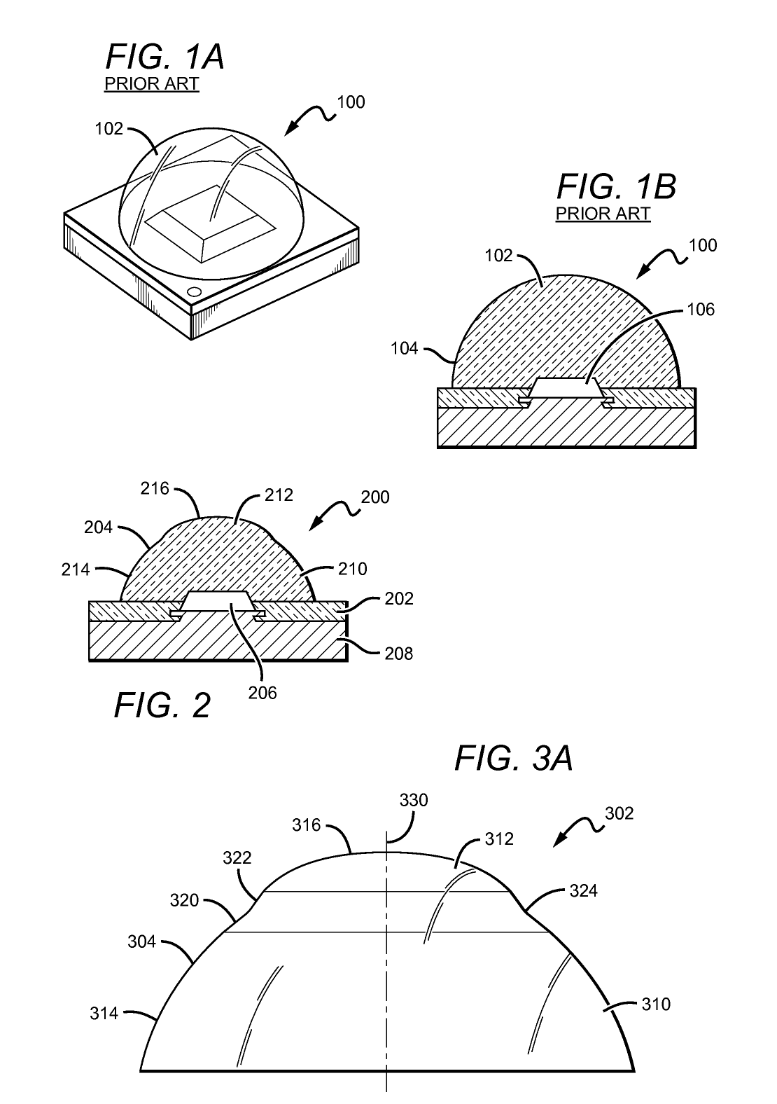

FIG. 2 shows a cross-sectional illustration of an LED package 200 according to an embodiment of the present invention. The package 200 comprises an encapsulant element 202 that is disposed above the light source(s) 206 such that substantially all of the light emitted from the source 206 passes through the encapsulant 202. The encapsulant 202 comprises a shaped primary emission surface 204.

The encapsulant 202 may be very thin such that it barely covers the bond wires, if they are used, or it can be much thicker. An acceptable range for both the largest width and the largest height of the encapsulant 202 is 70-200 micrometers in some applications, although other applications may dictate use of smaller or larger dimensions.

The encapsulant 202 may comprise any structure that is disposed above the source 206 as described above, and in one embodiment the encapsulant 202 comprises a lens used alone or in combination with other bonding materials to mount the lens over the source. The encapsulant 202 can be transparent, translucent, or luminescent, for example, and can be loaded with wavelength conversion materials, such as phosphors. The encapsulant 202 can be made of silicone, epoxy, glass, inorganic glass, spin-on glass, dielectrics, BCB, polyimides, polymers and hybrids thereof, and other materials, with the preferred material being silicone because of its high transparency and reliability in high power LED packages. Suitable phenyl- and methyl-based silicones are commercially available from Dow® Chemical. The encapsulant may perform functions such as beam shaping, collimating, and focusing, for example.

The encapsulant 202 may be formed in place over the source 206 as with a mold, or it may be fabricated separately and then subsequently attached to the light source 206 by an adhesive epoxy, for example. Different portions of an encapsulant 202 can be attached at different times, for example after the first portion has finished curing through fuse molding, or can be attached at the same time through molding. One large mold can be used to form many encapsulants over many sources on a wafer, as with overmolding. The entire encapsulant or portions of the encapsulant 202 may be applied with a pin-needle dispense method. In another embodiment, an ink jet may be used. Other dispense tools are also possible. Some encapsulant portions may be allowed to develop their shape using only gravity while they are cured, while some other portions may develop their shape through both gravity and other processes. Many different curing methods can be used, including but not limited to heat, ultraviolet (UV), infrared (IR). Methods for attaching an encapsulant to or forming an encapsulant on a surface are discussed in U.S. patent application Ser. No. 13/219,486 to Cree, Inc., which is fully incorporated by reference herein.

In the embodiment shown by FIG. 2, the encapsulant 202 comprises a lower portion 210 and an upper portion 212. The lower portion 210 is defined by a primary emission surface 214 similar to the surface 104, in that it is defined by a circular curve, although other curves are possible. Because in this embodiment the lower portion primary emission surface 214 is shaped similarly to the lower portion of a dome-shaped encapsulant, TIR for light emitted from the source 206 onto the lower portion primary emission surface 214 is minimized because rays of light encounter the surface 214 at near right angles. The package 200 therefore emits light efficiently at high angles.

The upper portion 212 of the encapsulant 202 is defined by a primary emission surface 216. Surface 216 differs from the prior art surface 104 in that surface 216 is non-spherical. In the embodiment of FIG. 2 the upper portion primary emission surface 216 is defined by a spline curve. A spline curve is a sufficiently smooth polynomial function that is piece-wise defined. Thus, a spline curve can itself contain two or more separate curves that combine to form the piece-wise polynomial function.

Other embodiments comprise emission surfaces defined by a single curve, such as a spline curve, comprise two curves, such as a lower portion circular curve and upper portion spline or circular curve, or comprise more than two different curvatures.

The package 200 may comprise several additional components. For example, in the embodiment shown the encapsulant 202 is disposed such that the encapsulant 202 and the source 206 are mounted on a common surface 208, such as a substrate, for example. The common surface 208 may be reflective. One effect of a reflective surface is to reduce the amount of light absorbed by the LED package 200. The package may also comprise a secondary optic for further beam-shaping purposes, as further discussed below.

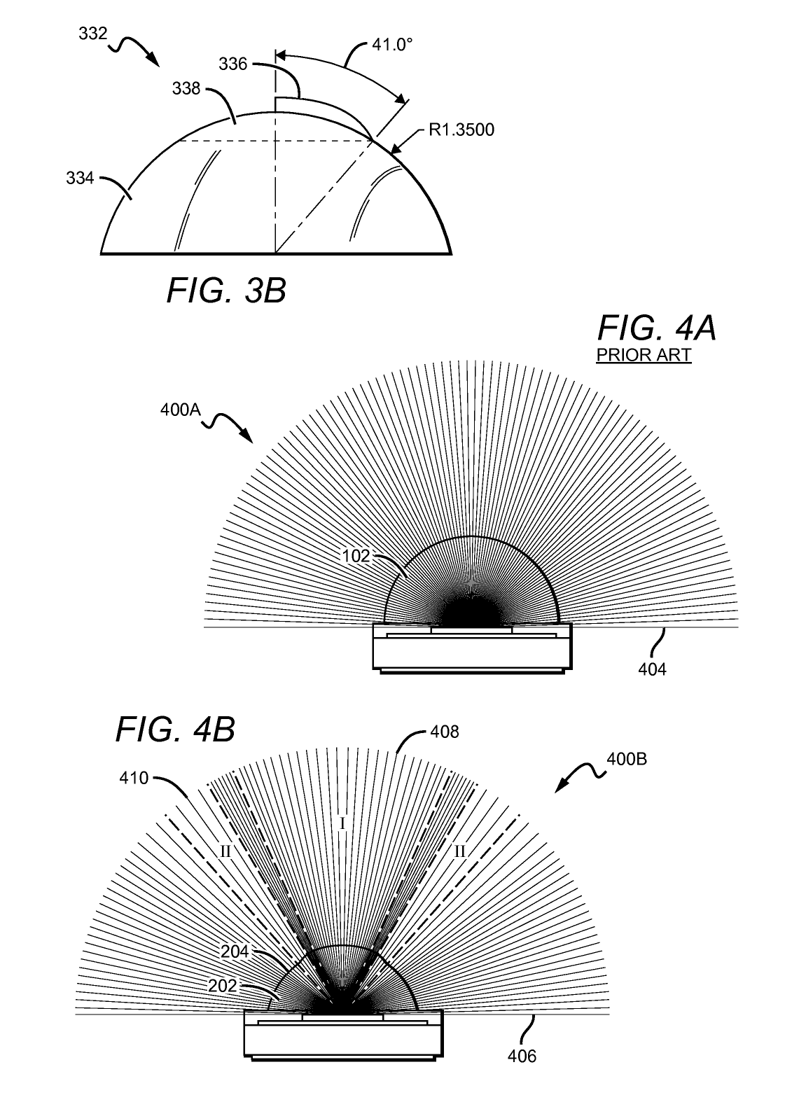

FIG. 3A shows a magnified cross-sectional view of an encapsulant 302 according to the present invention. The encapsulant 302 comprises a primary emission surface 304, which itself comprises a lower portion 314 and an upper portion 316. In the embodiment shown in this figure, both the lower portion 310 and upper portion 312 of the encapsulant are solids of revolution about an optical axis 330. The cross-sections of the primary emission surface 304 can be defined by curves. In some embodiments, the cross-section of lower portion 310 can be defined by a segment of a hemispherical curve. In some embodiments, the cross-section of the upper portion 312 can be defined by a spline curve.

In some embodiments, the primary emission surface 304 comprises portions 320 that are flatter than a similarly placed spherical portion and portions 322 that are steeper than a similarly placed spherical portion. In some embodiments, flat portions 320 refract light to a wider angle and steep portions 322 refract light to a narrower angle. In some embodiments, the transition 324 between the upper portion 316 and the lower portion 314 has a radius that acts to smooth the joining of the portions. In some embodiments, the transition 324 can be tangential to the curves of both the upper portion 316 and the lower portion 314.

The lower portion 314 and upper portion 316 of the primary emission surface 304 and the lower portion 310 and the upper portion 312 of the encapsulant 302 can be concave or convex, and can include a transition 324 between the two portions. The transition 324 can be smooth. In some embodiments, one or both of the upper portion and lower portion can be convex. In such embodiments, the transition 324 between the two portions can be defined by a different shape and/or can be concave. The curves of the primary emission surface can be designed such that no part of a concave portion falls below a part of the convex portion below. In other embodiments, more than three portions can be separated by distinct transitions; for example, one embodiment comprises upper, middle, and lower convex portions, with the upper and middle and the middle and lower portions separated by concave transitions.

In one embodiment, the lower portion 310 and the upper portion 312 comprise the same material, meaning that there is no internal refraction caused by the encapsulant (although internal refraction can be caused by phosphor within the encapsulant). In other embodiments, however, the portions of the encapsulant 302 comprise different materials. Another boundary through which light may pass is therefore formed, and light will refract at this boundary based upon the indexes of refraction of the portions 310 and 312. The materials of the portions can be chosen based upon the desired light output characteristics, taking into account other factors such as the shape of encapsulant 302.

FIG. 3B shows a dimensioned cross-sectional view of an encapsulant 332. The encapsulant has a dome shape defined by lower portion 334 and upper portion 338. However, the encapsulant 332 can be modified such that the upper portion fills the area between 338 and modified primary emitting surface 336 to form an encapsulant according to the current invention.

In some embodiments, warmer light (with a lower CCT) is refracted toward or away from the optical axis by the encapsulant, and/or cooler light (with a higher CCT) is refracted toward or away from the optical axis by the encapsulant. In some embodiments, warmer light may be refracted toward or away from the optical axis by flatter portions 320 or steeper portions 322 and/or cooler light may be refracted toward or away from the optical axis by flatter portions 320 or steeper portions 322.

FIG. 4A and FIG. 4B show ray traces of a prior art LED package 400A and an LED package according to the present invention 400B, respectively. Corresponding elements from FIG. 1 and FIG. 2 are referred to with the same identifying numbers. FIG. 4A shows the package 400A with a dome-shaped encapsulant 102 emitting light rays 404 in a standard ray trace pattern. FIG. 4B shows a scattered ray trace pattern that has been modified due to the shaped nature of encapsulant 202. The primary emission surface 204 refracts light in such a manner that some light rays 406 are unaffected, light rays 408 emitting in Section I (for example, within 20° of the optical axis 402 of the source 206) are pushed to emit from package 400B at a wider angle, and light rays 410 emitting from Section II (for example, between 25° and 40° from the optical axis 402 emit at an angle shifted inward). The angles covered by Section I and Section II can vary by package depending upon the package's intended use. Although the spline curve in this embodiment alters the emission angle of light rays from 0° to 20° and 25° to 40° off the optical axis 402, other embodiments can be tailored to refract light emitted from the LED chip at other narrow or wide angles either toward or away from the optical axis. Intermediate zones of refraction between the above angles are also possible; for example, some embodiments may refract light from 20° to 60° inward or outward.

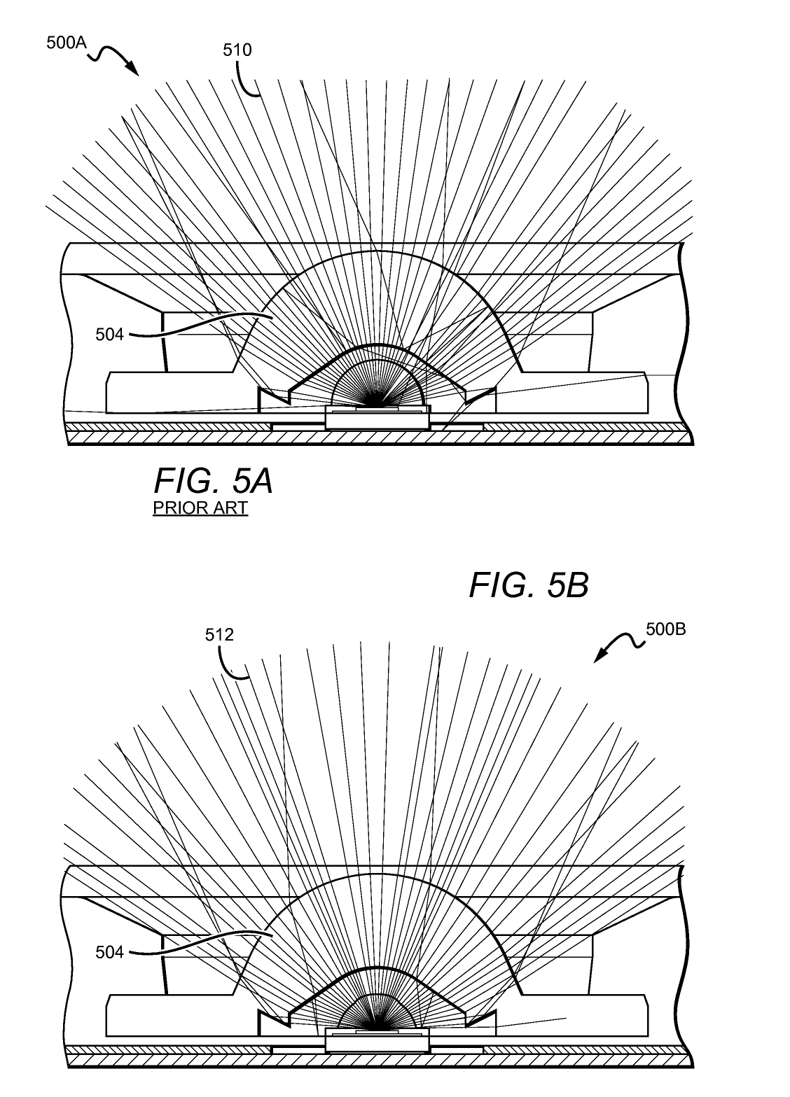

FIG. 5A and FIG. 5B show ray traces of a prior art LED package 500A and an LED package according to the present invention 500B. In this embodiment, the respective packages each comprise a secondary optic 504. As can be seen by the ray trace 510 of package 500A and the ray trace 512 of package 500B, the mixing effect shown by FIG. 4A and FIG. 4B is enhanced by the presence of the secondary optic 504.

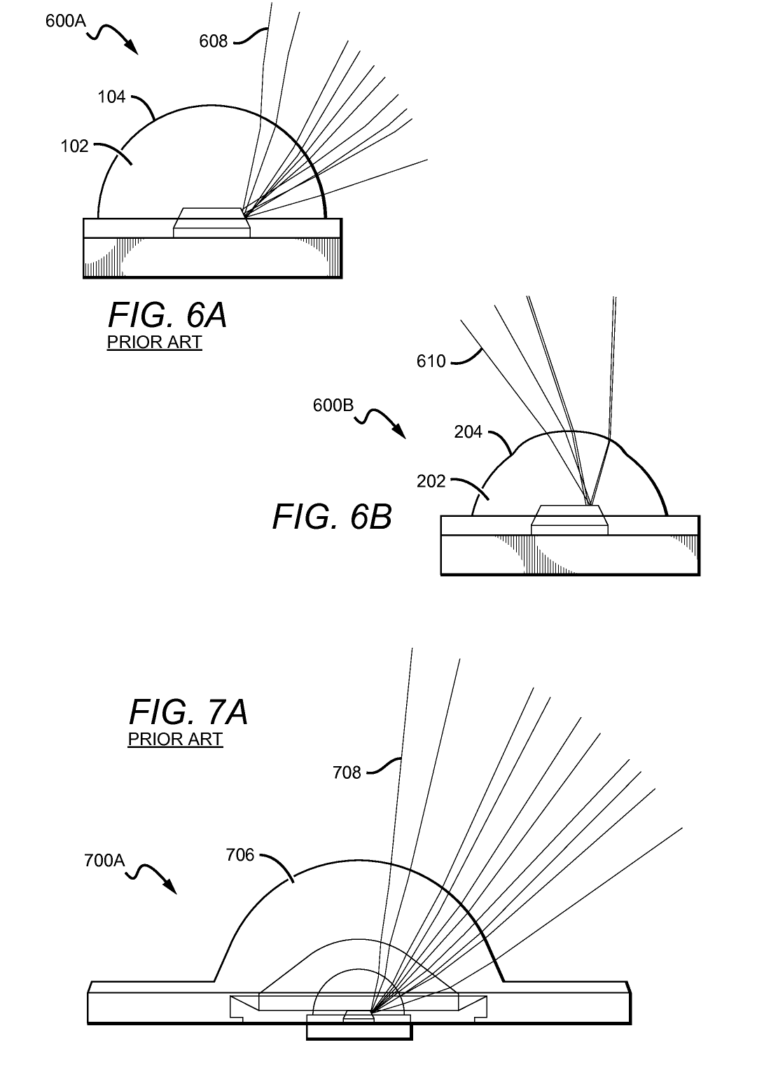

FIG. 6A and FIG. 6B show high intensity blue light (480 nm) leakage for a prior art LED package 600A and an LED package according to the present invention 600B, respectively; neither in this case comprises secondary optics. Prior art package 600A comprises prior art encapsulant 102 and emits blue light rays 608. In this case, blue light rays 608 are only slightly refracted by the encapsulant, with some rays 608 passing straight through the primary emission surface 104.

LED package 600B is a package according to an embodiment of the present invention. This package comprises encapsulant 202 and primary emission surface 204, and emits blue light rays 610. The primary emission surface 204 is shaped to refract blue light rays 610 in such a manner as to improve the CSU of the package 600B.

Package 700A is similar to package 600A, but further comprises a secondary optic 706. In this embodiment the secondary optic 706 is a Petroleum Symmetric (PS) secondary optic, such as is commercially available from Cree, Inc., although other secondary optics are possible. Blue light rays 708 do not experience any significant refraction at any boundary of materials.

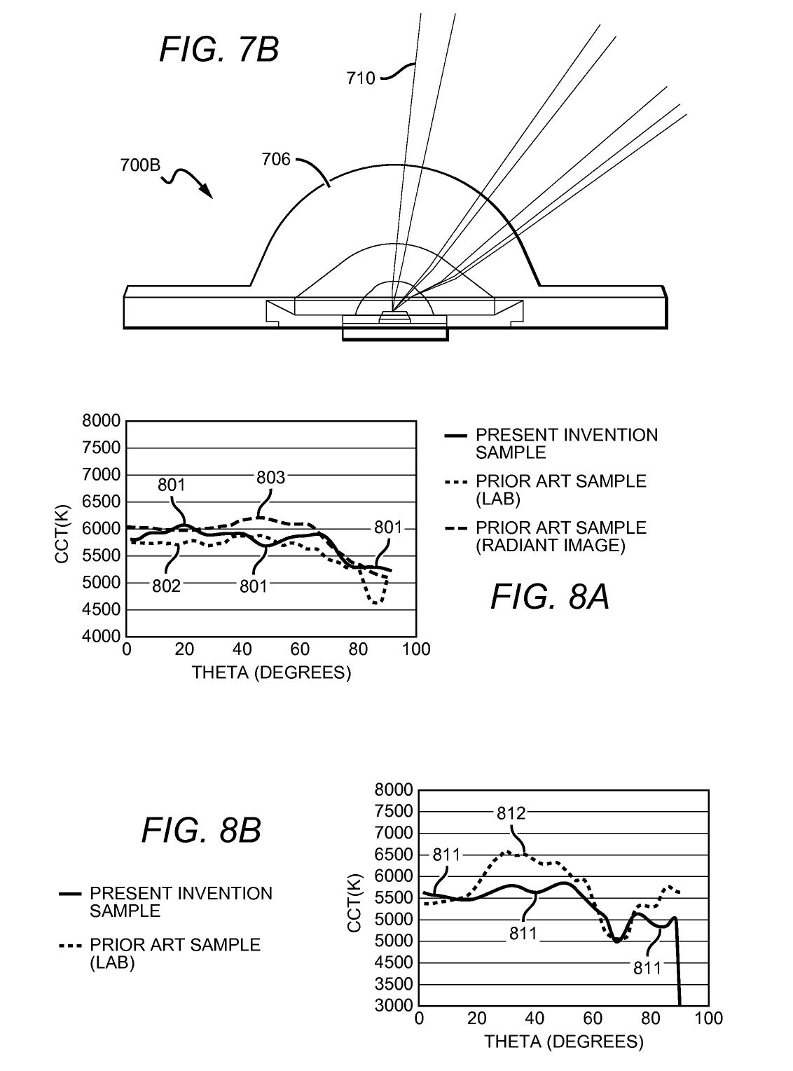

Package 700B comprises an encapsulant according to the present invention 202 and primary emission surface 204, as well as secondary optic 706. The package 700B emits blue light rays 710, which can be seen to refract. Such refraction blends the light rays of various CCTs in order to improve CSU over the prior art package shown in FIG. 7A.

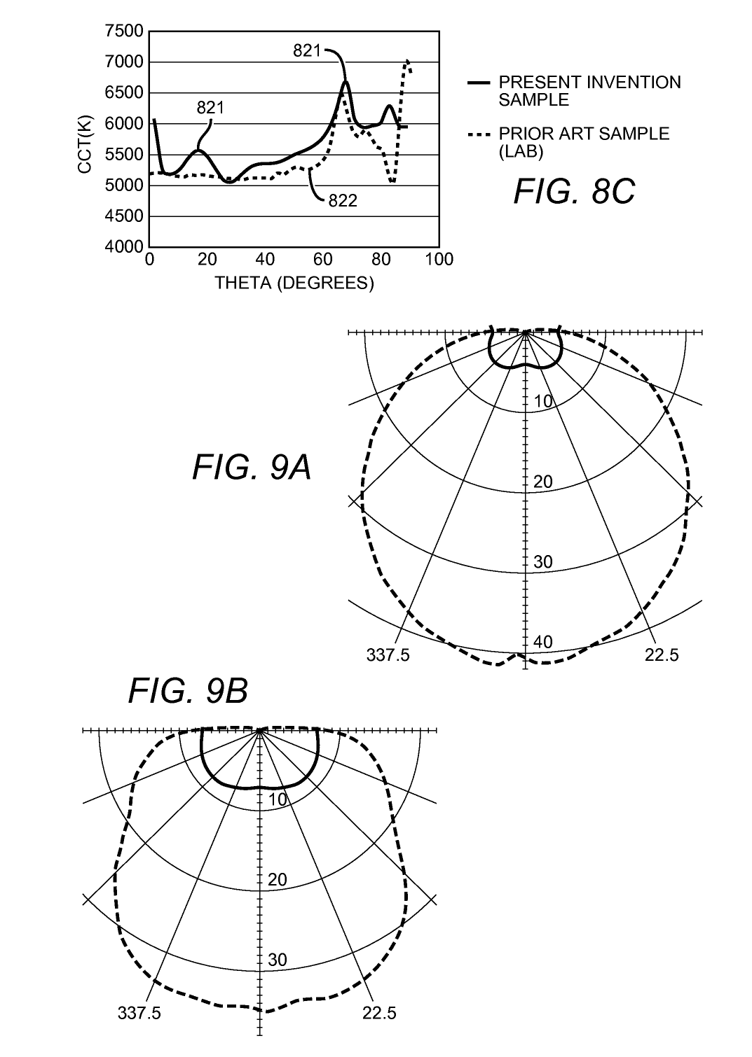

In FIG. 8A, FIG. 88, and FIG. 8C, the CCT by angle for devices according to the current invention are estimated using LightTools®. LightTools® is a 3D optical engineering and design software product used to predict light output characteristics. It is a known tool to those skilled in the art of optical engineering, and is known to produce verifiable predictable light output models that correlate with the output characteristics of final products.

FIG. 8A shows a sample graph of CCT vs. emission angle of a prior art LED package and an LED package according to the present invention, respectively, wherein no secondary optics are utilized. One goal of the present invention is to improve the CSU of an LED package. A package with good CSU will have relatively constant CCT across a wide range of angles. The OCT of a device according to the present invention is shown by line 801. Laboratory measurements of a prior art device are shown by line 802, and a radiant image of a prior art device is shown by line 803. Line 801 begins with a CCT of about 5800K at 0° and remains near constant until an angle of around 65°, before falling to a CCT of about 5300K from 80° to 90°. The fact that line 801 remains near constant until such a wide angle, and even beyond this angle only falls by about 500K, represents the fact that a package according to the present invention displays high CSU. The prior art device represented by line 802, on the other hand, begins falling from around 5800K at 45° to about 5300K at 80°, then drops rapidly to a CCT of 4600K beyond 80°, indicating poor CSU. Similarly, line 803 begins at 6000K at 0°, rises to 6300K at 45°, and then begins to fall at a somewhat constant rate until reaching 5100K at 85°, indicating poor CSU at angles wider than 45°.

Packages according to the present invention often comprise secondary optics. While CSU is improved by the present invention in LED packages not comprising secondary optics as seen in FIG. 8A, this effect is often even more apparent in packages that utilize secondary optics. FIG. 83 shows a comparison of CCT vs. emission angle for devices comprising a PS secondary optic. Line 811 shows the CCT of a device according to the present invention, while 812 shows the OCT of a prior art device. Line 811 begins at a CCT of about 5500K, and remains between 5200K and 5800K from 0° and 60°. While CSU somewhat deteriorates at greater angles, the CCT of line 811 remains between 4500K and 5200K between 60° and 90°. Line 812, on the other hand, begins at around 5400K at 0° and rises to a peak of over 6500K at about 30°, then falls to 4500K at about 70° before rising again to 5700K near 90°. As shown by FIG. 8B, a package according to the present invention and further comprising a PS secondary optic shows much better CSU than a prior art device.

FIG. 8C shows a comparison of CCT vs. emission angle for devices comprising a T5 secondary optic designed for peak emission at wide angles. Line 821 shows the CCT of a device according to the present invention, while 822 shows the CCT of a prior art device. Line 821 remains at a CCT of between about 6000K and 6700K at angles between 60° and 85°. Line 822, on the other hand, fluctuates between 5000K and 7000K at such angles, thus displaying poor CSU at the most crucial viewing angles. Clearly the package according to the present invention displays a marked improvement in CSU over the prior art device.

FIG. 9A and FIG. 9B show sample photometric polar distributions of a prior art LED package and an LED package according to the present invention, respectively, wherein no secondary optics are utilized. One goal of the present invention is to mitigate any effect on photometric polar light distribution and extraction efficiency such that these qualities are within acceptable levels. As can be seen when comparing FIG. 9A and FIG. 9B, the photometric polar distribution of the packages is substantially similar to the distribution of a package using a dome-shaped encapsulant 102. Further, FIG. 9B shows that luminous intensity is only minimally affected, as it is at least 80% of that of FIG. 9A at any emission angle.

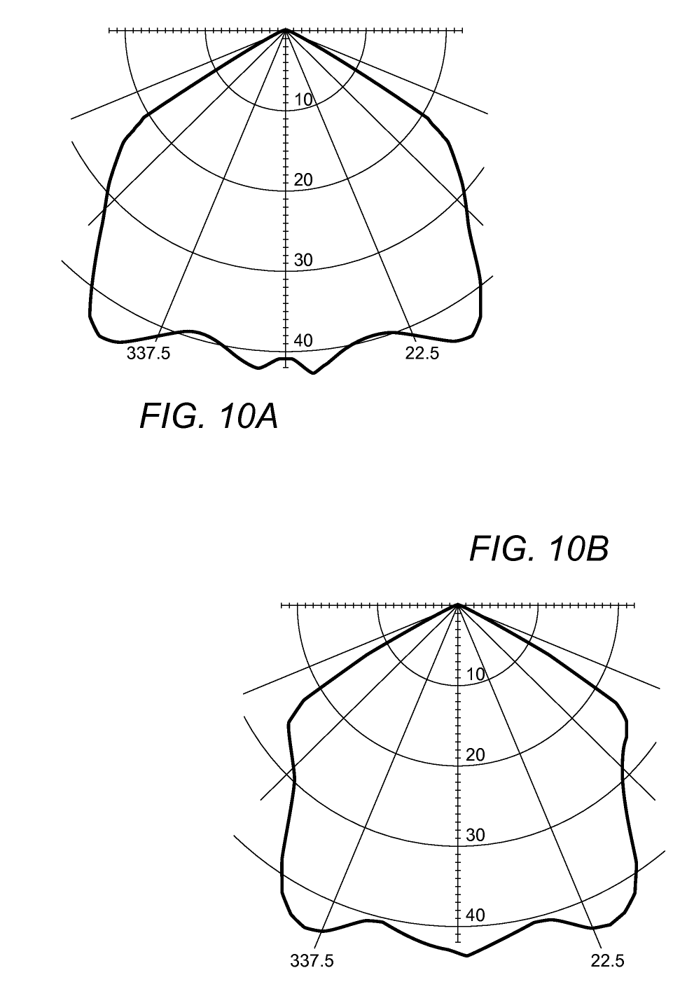

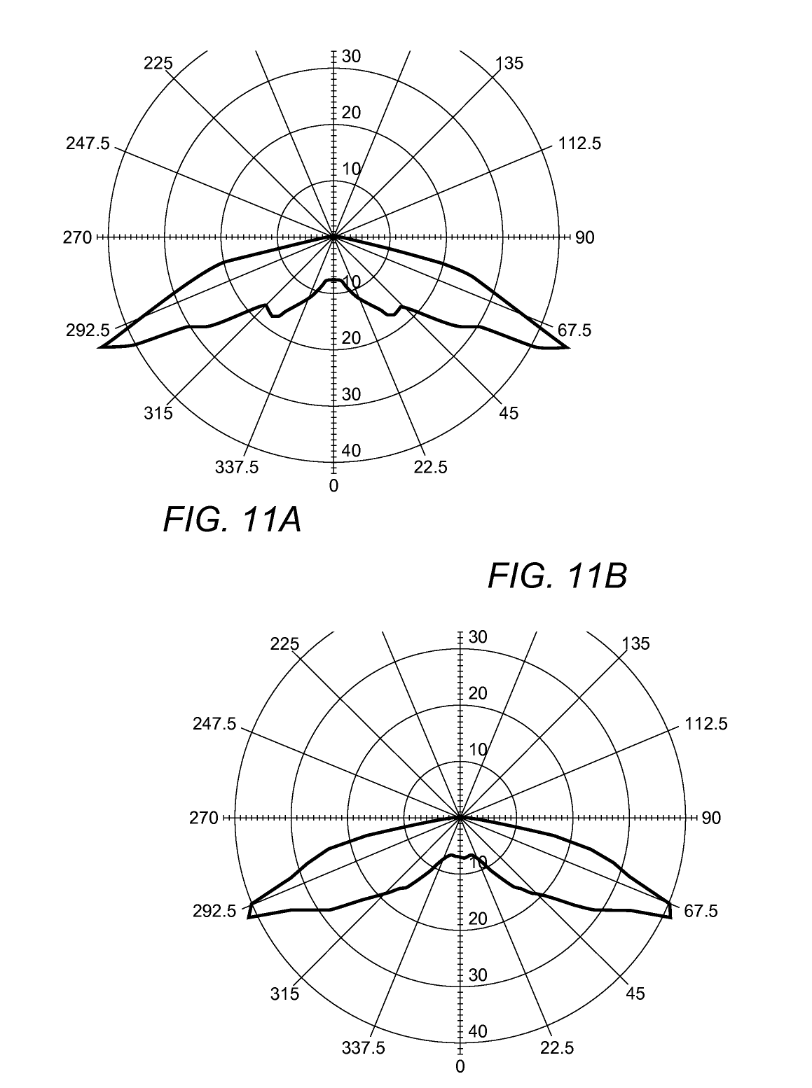

FIG. 10A and FIG. 10B show sample photometric polar distributions of a typical LED package and an LED package according to the present invention, respectively. Both packages comprise a PS secondary optic. As can be seen from the figures, the photometric polar distributions of the packages are very similar in both shape and magnitude, indicating that the effect on photometric polar distribution of an encapsulant according to the present invention such as 202 is minimal.

FIG. 11A and FIG. 11B show sample photometric polar distributions of a prior art LED package and an LED package according to the present invention, respectively. Both packages comprise a T5 secondary optic designed for wide angle emission. In this case, FIG. 11A and FIG. 11B show the photometric polar distributions of LED packages each comprising a T5 secondary optic, which is designed for high emission at wide angles. As can be seen from the figures, the photometric polar distributions of the packages are very similar in both shape and magnitude, indicating that the effect of an encapsulant according to the present invention such as 202 is minimal.

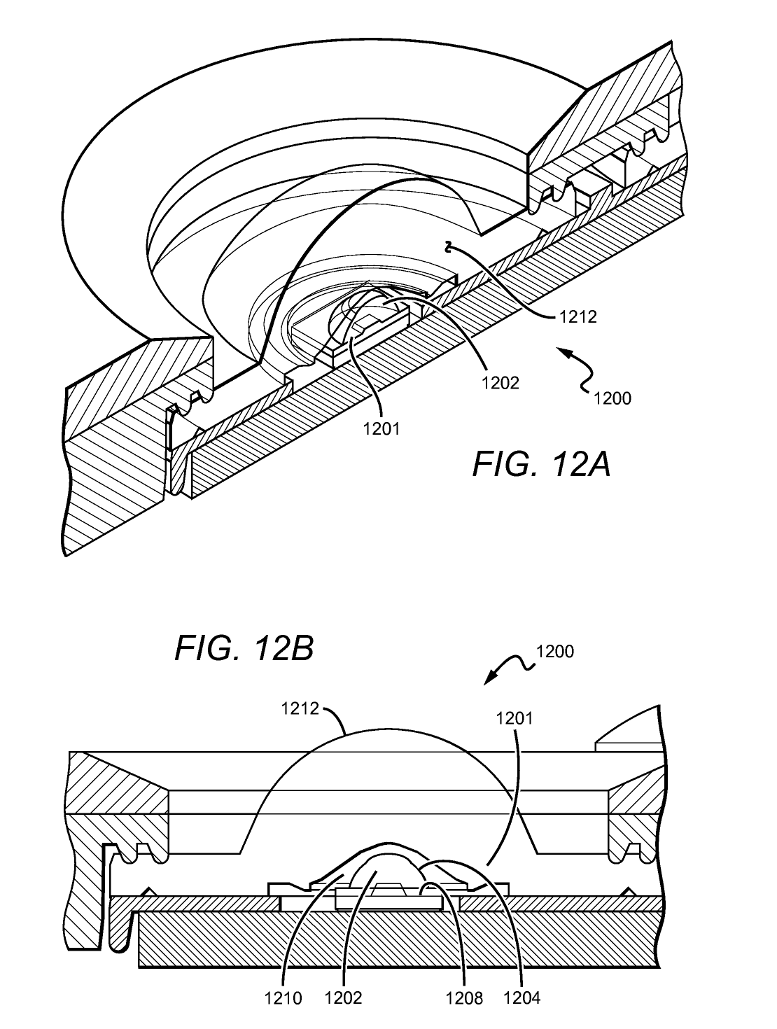

FIGS. 12A and 12B show a perspective and a front view of a light emitting system 1200, respectively. The system 1200 comprises a light emitting package according to the present invention 1201, which itself comprises a secondary optic 1212. In some embodiments, the secondary lens or secondary optic may have an inner surface that partially or completely surrounds or partially or completely covers the encapsulant and/or primary lens. If the inner surface of the secondary optic covers the encapsulant in an embodiment of the present invention, the secondary optic and encapsulant should preferably have different indexes of refraction. In some embodiments, there may be a space between the encapsulant and/or primary lens and the secondary lens. In prior art devices this space is filled with an optical index-matching gel to minimize refractive losses; however, in embodiments of the present invention such a gel should not match the refractive index of the encapsulant, as some refraction is necessary to achieve the desired CSU. In some embodiments, the secondary optic may be remote from the LED chip, the mount surface, the primary lens, the encapsulant, or any combination of these.

In the embodiment of FIG. 12A and FIG. 12B, the light emitting system comprises a light bar assembly, although other systems may comprise light engines or other types of light emitting systems. Light emitting system 1200 comprises a source (not shown), an encapsulant 1202, the primary emission surface 1204 of the encapsulant 1202, and a mount surface 1208. The primary emission surface 1204 in this embodiment is substantially surrounded by a space 1210. In this embodiment space 1210 is a void; however, in other embodiments space 1210 can comprise a transparent adhesive or any other material. Light emitting system 1200 also comprises secondary optic 1212. Light emitted through encapsulant 1202 exits the primary emission surface 1204 and enters space 1210. Once it passes through the space 1210, light encounters secondary optic 1212, which is designed based on the desired emission characteristics of the system 1200. The CSU of the system 1200 may be dramatically improved by using the encapsulant 1202 as opposed to a prior art encapsulant.

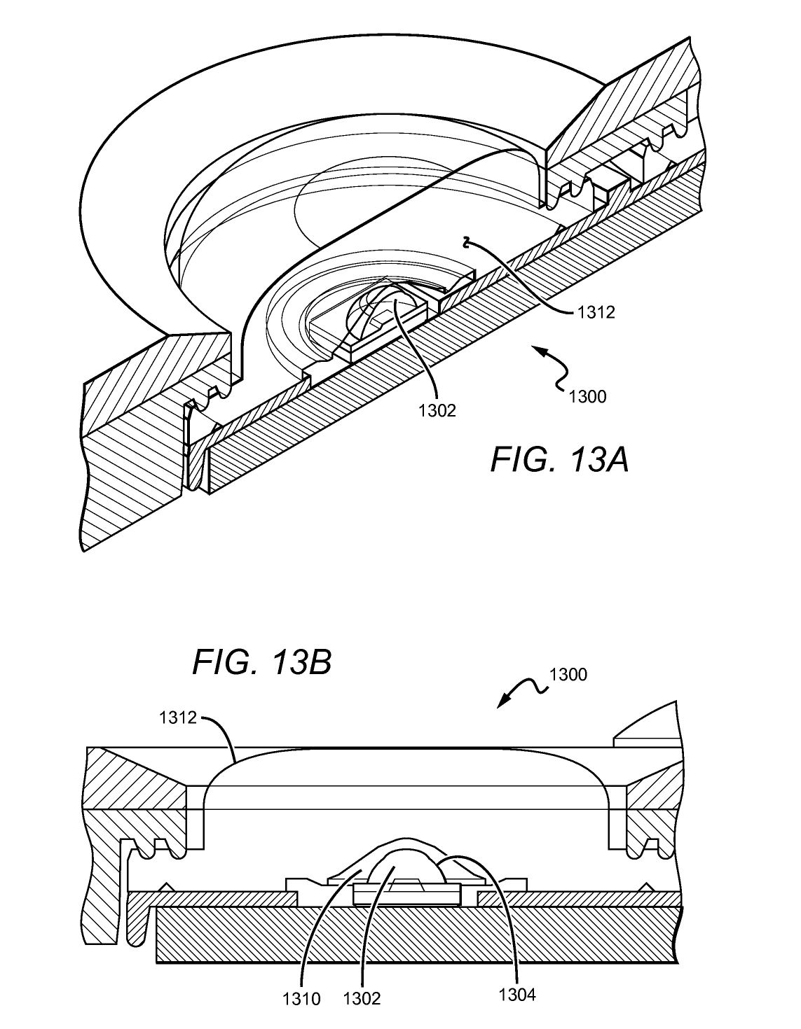

FIGS. 13A and 13B show a perspective and a front view of a second light emitting system according to the present invention 1300. Light emitting system 1300 is similar to system 1200, but comprises a different secondary optic 1312. In this case, the secondary optic 1312 is designed to refract rays of light to wider angles. The CSU of the system 1300 may be dramatically improved by using the encapsulant 1302 as opposed to a prior art encapsulant.

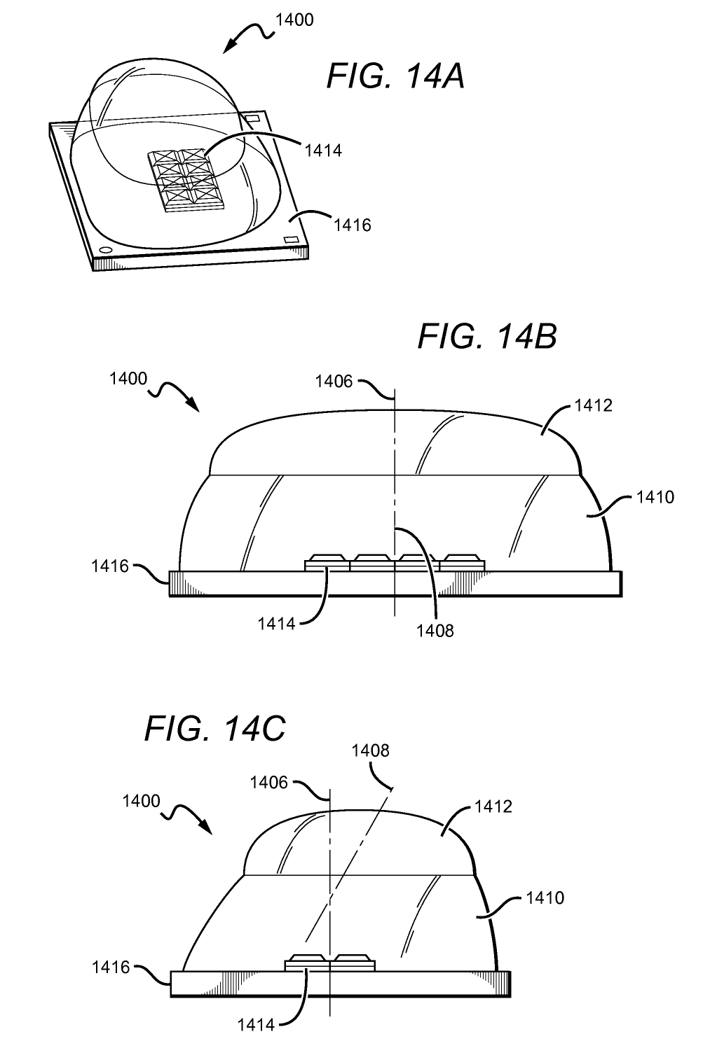

FIG. 14A, FIG. 14B, and FIG. 14C show perspective, front, and side views respectively of another LED package according to the present invention. The package 1400 is similar to device 200, and is formed using similar manufacturing techniques. Package 1400 comprises source 1414, substrate 1416, and an encapsulant 1402 with lower and upper portions 1410 and 1412. In this embodiment, neither portion is symmetric about the source optical axis 1406. In other embodiments one portion may be symmetric while another portion is not. The asymmetric lower and upper portions 1410 and 1412 are designed to emit light and blend rays of different CCTs in accordance with the desired final emission characteristics, and can greatly improve CSU and other emission characteristics over prior art packages. In other embodiments, one or both of the portions 1410 and 1412 can be shapes that are not centered about the source 1414, as can be seen in FIG. 14C. Further, the source 1414 can be displaced from the center of the substrate 1416. While in previous embodiments the source optical axis and package optical axis are coincident, the source optical axis 1406 and the package optical axis 1408 are not coincident.

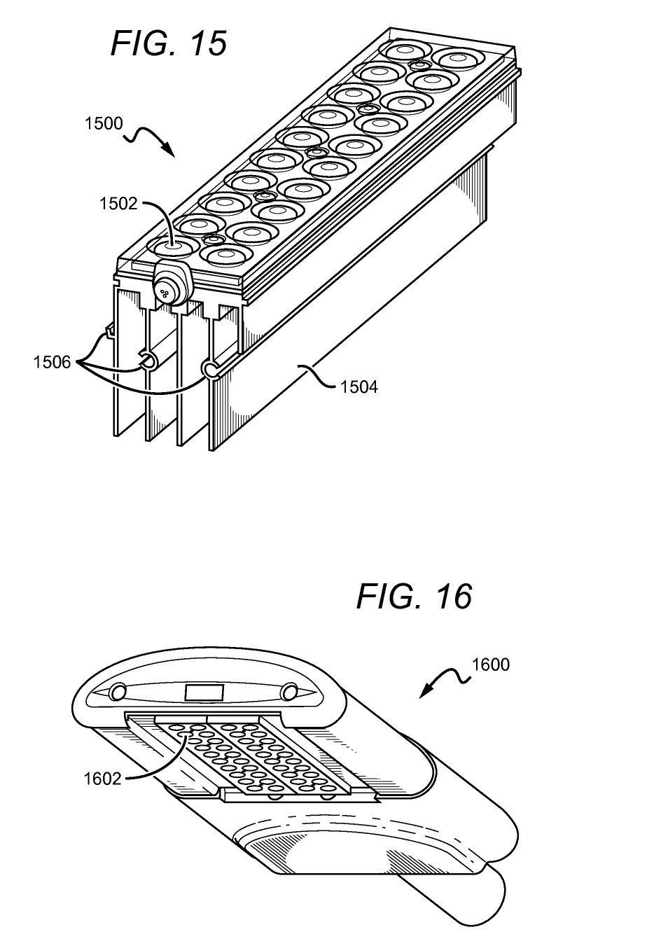

FIG. 15 shows a perspective view of a lighting unit comprising LED packages according to the present invention. Lighting unit 1500 comprises LED packages 1502 and heat sink 1504, which itself comprises attachment features 1506. Lighting unit 1500 can comprise one type of LED package or many types of LED packages, including but not limited to the package embodiments shown in FIG. 2 and/or FIG. 14, based upon the desired lighting unit output. Due to the use of LED packages according to the present invention, lighting unit 1500 will exhibit improved CSU over a prior art lighting unit.

FIG. 16 shows a perspective view of a downlight fixture comprising LED packages according to the present invention. Downlight fixture 1600 can be used in a number of applications, including for street light and gas station lighting. Downlight fixture 1600 can comprise one type of LED package or many types of LED packages, including but not limited to the package embodiments shown in FIG. 2 and/or FIG. 14. Due to the use of LED packages according to the present invention, downlight fixture 1600 will exhibit improved CSU over a prior art fixture.

It is understood that embodiments presented herein are meant to be exemplary. Embodiments of the present invention should not be limited to those expressly illustrated and discussed; for example, a possible embodiment involves a non-LED optical emitter package comprising lower, middle, and upper portions of an encapsulant, each with a primary emission surface defined by a different spline curve in order to achieve improved CSU.

Although the present invention has been described in detail with reference to certain preferred configurations thereof, other versions are possible. Therefore, the spirit and scope of the invention should not be limited to the versions described above.

We claim:

1. A light emitting diode (LED) package, comprising:
at least one LED chip;
an encapsulant proximate to said LED chip, said encapsulant comprising an upper portion defined by a first shape and a lower portion defined by a second shape;
said upper portion and said lower portion combining to improve the color spatial uniformity of the package emission compared to a package with an encapsulant consisting of one portion.

2. The package of claim 1, wherein said upper portion is non-spherical.

3. The package of claim 1, wherein the cross-section of said first shape is defined by a spline curve.

4. The package of claim 3, wherein said spline curve is defined by at least two curves.

5. The package of claim 1, wherein the cross-section of said second shape is defined by a circular segment.

6. The package of claim 1, wherein the transition between said upper portion and said lower portion is smooth.

7. The package of claim 1, wherein at least one of the upper portion and the lower portion is a solid of revolution about an optical axis.

8. The package of claim 1, wherein the upper portion and the lower portion are solids of revolution about an optical axis.

9. The package of claim 1, wherein said encapsulant refracts at least some of a first portion of light emitted from said LED chip away from an optical axis.

10. The package of claim 9, wherein said first portion of light is emitted from said LED chip at an angle between 0° and 20° from an optical axis.

11. The package of claim 1, wherein said encapsulant refracts at least some of a second portion of light emitted from said LED chip toward an optical axis.

12. The package of claim 11, wherein said second portion of light is emitted from said LED chip at an angle between 25° and 40° from an optical axis.

13. The package of claim 1, wherein said encapsulant refracts at least some light of a first CCT range away from an optical axis.

14. The package of claim 13, wherein said first CCT range is 1500K to 3500K.

15. The package of claim 1, wherein said encapsulant refracts at least some light of a second CCT range toward an optical axis.

16. The package of claim 15, wherein said second CCT range is 7000K to 9000K.

17. The package of claim 1, wherein at least one of said encapsulant portions is asymmetric.

18. The package of claim 1, wherein said at least one LED chip has an optical axis;
wherein at least one of said encapsulant portions is asymmetric about said optical axis.

19. The package of claim 1, wherein said first shape has a first index of refraction and said second shape has a second index of refraction.

20. The package of claim 1, further comprising a substrate;
wherein the center of said at least one LED chip is displaced from the center of said substrate.

21. The package of claim 1, further comprising a secondary optic.

22. The package of claim 21, wherein said secondary optic is proximate said encapsulant.

23. The package of claim 21, wherein said secondary optic is on said encapsulant.

24. The package of claim 21, wherein an inner surface of said secondary optic covers said encapsulant.

25. The package of claim 21, wherein said secondary optic and said encapsulant are on a mount surface.

26. The package of claim 21, wherein there is a space between said encapsulant and said secondary optic.

27. The package of claim 21, wherein said secondary optic is remote from said encapsulant.

28. The package of claim 1, wherein said encapsulant is on a reflective mount surface.

29. The package of claim 1, wherein said encapsulant comprises a wavelength conversion material.

30. The package of claim 1, wherein said encapsulant comprises a textured emission surface.

31. The package of claim 1, wherein said encapsulant adheres directly to said LED chip and a mount surface.

32. The package of claim 1, wherein said encapsulant is attached to said LED chip with an adhesive epoxy.

33. The package of claim 29, wherein said LED package emits a light combination of at least two different spectra.

34. The package of claim 29, wherein said LED package emits a white light combination of blue light and yellow light.

35. An emitter encapsulant comprising an upper portion defined by a first shape and a lower portion defined by a second shape;
wherein the cross-section of said first shape is defined by a spline curve.

36. The emitter encapsulant of claim 35, wherein said spline curve is defined by at least two curves.

37. The emitter encapsulant of claim 35, wherein the cross-section of said second shape is defined by a circular segment.

38. The emitter encapsulant of claim 35, wherein said encapsulant refracts at least some of a first portion of light emitted from said LED chip away from an optical axis and refracts at least some of a second portion of light emitted from said LED chip toward an optical axis.

39. A light emitting system comprising:
at least one LED chip;
an encapsulant proximate to said LED chip, said encapsulant comprising an upper portion defined by a first shape and a lower portion defined by a second shape;
a secondary optic at least partially surrounding said encapsulant;
said encapsulant improving the color spatial uniformity of the package emission compared to a package with an encapsulant consisting of one portion.

40. The light emitting system of claim 39, wherein said first curve is a spline curve.

41. The light emitting system of claim 39, wherein said spline curve is defined by at least two curves.

42. The light emitting system of claim 39, wherein said second curve is a circular segment.

43. The light emitting system of claim 39, wherein said encapsulant refracts at least some of a first portion of light emitted from said LED chip away from an optical axis and refracts at least some of a second portion of light emitted from said LED chip toward an optical axis.

44. A light emitting diode (LED) package, comprising:
an optical axis;
at least one LED chip; and
an encapsulant proximate to said LED chip;
wherein said encapsulant refracts at least some of a first portion of light emitted from said LED chip away from said optical axis and refracts at least some of a second portion of light emitted from said LED chip toward said optical axis.

45. The package of claim 44, wherein said first portion of light is closer to said optical axis than said second portion of light.

46. The package of claim 44, wherein said first portion of light has a lower average CCT than said second portion of light.

47. A light emitting diode (LED) package, comprising:
a source comprising at least one LED chip;
an encapsulant proximate to said LED chip, said encapsulant comprising an upper portion defined by a first shape and a lower portion defined by a second shape;
wherein a source optical axis and a package optical axis are not coincident.

48. The package of claim 47, wherein at least one of said upper portion and said lower portion is asymmetric.

49. The package of claim 47, wherein at least one of said upper portion and said lower portion is displaced from said source optical axis.

50. The package of claim 47, further comprising a substrate, wherein said source is displaced from the center of said substrate.

51. A method of fabricating a light emitting diode (LED) package, comprising:
providing a mount surface;
disposing at least one LED chip on said mount surface;
depositing a first encapsulant section having a first shape on said at least one LED chip;
curing said first encapsulant section;
depositing a second encapsulant section having a second shape on said first encapsulant section; and
curing said second encapsulant section.

52. The method of claim 51, wherein said encapsulant sections are shaped by molding as each encapsulant section is cured.

53. The method of claim 51, wherein said encapsulant sections are cured simultaneously.

54. The method of claim 51, wherein said encapsulant sections are simultaneously shaped by molding and simultaneously cured.

55. The method of claim 51, wherein said second encapsulant section is cured after said first encapsulant section is cured.

56. The method of claim 51, wherein said second encapsulant section is deposited using a pin-needle dispense method.

57. The method of claim 51, wherein said second encapsulant section is deposited using an ink jet.

58. The method of claim 51, wherein the shape of said second encapsulant section is formed by allowing the second encapsulant section to settle using only gravity.

59. A method of fabricating a plurality of light emitting diode (LED) packages, comprising:
providing an LED wafer;
disposing a plurality of LED chips on said LED wafer;
depositing a plurality of first encapsulant sections having a first shape on said plurality of LED chips;
curing said first encapsulant sections;
depositing a plurality of second encapsulant sections having a second shape on said plurality of LED chips;
curing said second encapsulant sections;
wherein said encapsulant sections are shaped by a mold while cured.

60. The method of claim 59, further comprising singulating said LED packages from said wafer.

61. A light emitting diode (LED) package, comprising:
at least one LED chip;
an encapsulant proximate to said LED chip, said encapsulant comprising an upper portion defined by a first shape and a lower portion defined by a second shape;
wherein said first shape and said lower shape are convex.

62. The package of claim 61, wherein said upper portion and said lower portion are connected by a middle portion defined by a third shape;
wherein said third shape is concave.

63. The package of claim 61, wherein said first shape is defined by a circular segment and said second shape is defined by a circular segment.

64. The package of claim 62, wherein said third shape is defined by a circular segment.

65. The package of claim 62, wherein said first shape, said second shape, and said third shape are defined by circular segments.

66. The package of claim 62, wherein no part of said third shape falls below a part of said second shape.

67. The package of claim 61, wherein a transition between said upper portion and said lower portion is smooth.

68. The package of claim 61, wherein said upper portion is non-spherical.
